(19) United States
(12) Patent Application Publication
(10) Pub. No.: US 2021/0143056 A1
(43) Pub. Date: May 13, 2021

(54) SPACER-BASED CONDUCTOR CUT

(71) Applicant: QUALCOMM Incorporated, San Diego, CA (US)

(72) Inventors: John Jianhong ZHU, San Diego, CA (US); Junjing BAO, San Diego, CA (US); Giridhar NALLAPATI, San Diego, CA (US)

(21) Appl. No.: 16/676,715

(22) Filed: Nov. 7, 2019

(51) Int. Cl. H01L 21/768; H01L 21/033; H01L 21/311; H01L 23/522; H01L 23/528

(52) U.S. Cl. CPC H01L 21/76816; H01L 21/0337; H01L 23/528; H01L 23/5226; H01L 21/31144

(57) ABSTRACT

Certain aspects of the present disclosure generally relate to methods of fabricating integrated circuits. An example method generally includes forming a first cavity in a first layer disposed above a second layer and filling at least a portion of the first cavity with a dielectric material disposed above the second layer. The method further includes forming a second cavity in the dielectric material such that the dielectric material remaining in the first cavity is disposed on (e.g., conforms to) lateral surfaces of the first layer in the first cavity and forming a dielectric spacer comprising a segment of the remaining dielectric material in the first cavity. The method also includes forming a first conductor, in the first layer or the second layer, that is laterally spaced from a second conductor based at least in part on a width of the dielectric spacer.

### BACKGROUND

### Field of the Disclosure

Certain aspects of the present disclosure generally relate to electronic circuits and, more particularly, to various techniques for forming an electrically insulating spacer between conductors of a conductive layer in an integrated circuit.

### Description of Related Art

As electronic devices are getting smaller and faster, the demand for integrated circuits (ICs) with higher I/O count, faster data processing rate, and/or better signal integrity greatly increases. The ICs may include various layers of conductors disposed between layers of dielectric material, which are formed during a back-end-of-line (BEOL) fabrication process. The conductors facilitate electrical routing to various electrical components including transistors, amplifiers, inverters, control logic, memory, power management circuits, buffers, filters, resonators, capacitors, inductors, resistors, etc.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include improved layouts of conductive layers for integrated circuits.

Certain aspects of the present disclosure provide a method of fabricating an integrated circuit. The method generally includes forming a first cavity in a first layer disposed above a second layer and filling at least a portion of the first cavity with a dielectric material disposed above the second layer. The method further includes forming a second cavity in the dielectric material such that the dielectric material remaining in the first cavity is disposed on lateral surfaces of the first layer in the first cavity and forming a dielectric spacer comprising a segment of the remaining dielectric material in the first cavity. The method also includes forming a first conductor, in the first layer or the second layer, that is laterally spaced from a second conductor based at least in part on a width of the dielectric spacer.

Certain aspects of the present disclosure provide an integrated circuit. The integrated circuit generally includes a first conductive layer, a second conductive layer, a first via, a second via, and an insulating spacer. The first conductive layer comprises a first conductor and a second conductor laterally spaced from the first conductor. The second conductive layer is disposed above the first conductive layer, where the second conductive layer comprises a third conductor and a fourth conductor laterally spaced from the third conductor. The first via is disposed between the first conductive layer and the second conductive layer and electrically coupled to the first conductor and the third conductor. The second via is disposed between the first conductive layer and the second conductive layer and electrically coupled to the second conductor and the fourth conductor. The insulating spacer disposed between the third conductor and the fourth conductor, where the third conductor is laterally spaced from the fourth conductor by a distance between the first conductor and the second conductor with or without an effective space for a single conductor disposed between the first conductor and the second conductor.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a cross-sectional view of an example integrated circuit having an insulating spacer, in accordance with certain aspects of the present disclosure.

FIG. 2A is a top view of an insulating spacer disposed between conductors with an effective space for another conductor, in accordance with certain aspects of the present disclosure.

FIG. 2B is a top view of an insulating spacer disposed between conductors without an effective space for another conductor, in accordance with certain aspects of the present disclosure.

FIG. 3A illustrates a top view and a cross-sectional view of a photoresist layer with a cavity disposed above a dielectric layer, in accordance with certain aspects of the present disclosure.

FIG. 3B illustrates a top view and a cross-sectional view of a dielectric material filled in the cavity of the photoresist layer of FIG. 3A, in accordance with certain aspects of the present disclosure.

FIG. 3C illustrates a top view and a cross-sectional view of one or more spacers formed from the dielectric material of FIG. 3B, in accordance with certain aspects of the present disclosure.

FIG. 4A illustrates a cross-sectional view of a spacer embedded in a photoresist layer disposed above a dielectric layer, in accordance with certain aspects of the present disclosure.

FIG. 4B illustrates a cross-sectional view of trenches formed in the dielectric layer of FIG. 4A, in accordance with certain aspects of the present disclosure.

FIG. 4C illustrates a cross-sectional view of conductive material filled in the trenches of FIG. 4B, in accordance with certain aspects of the present disclosure.

FIG. 5A illustrates a top view and a cross-sectional view of a spacer embedded in a first dielectric layer disposed above a second dielectric layer, in accordance with certain aspects of the present disclosure.

FIG. 5B illustrates a cross-sectional view of a photoresist layer disposed above the first dielectric layer of FIG. 5A, in accordance with certain aspects of the present disclosure.

FIG. 5C illustrates a cross-sectional view of trenches formed in the first dielectric layer of FIG. 5B, in accordance with certain aspects of the present disclosure.

FIG. 5D illustrates a cross-sectional view of conductive material filled in the trenches of FIG. 5C, in accordance with certain aspects of the present disclosure.

FIG. 6A illustrates a top view and a cross-sectional view of a photoresist layer with a cavity disposed above a conductive layer, in accordance with certain aspects of the present disclosure.

FIG. 6B illustrates a top view and a cross-sectional view of a dielectric material filled in the cavity of the photoresist layer of FIG. 6A, in accordance with certain aspects of the present disclosure.

FIG. 6C illustrates a top view and a cross-sectional view of another cavity that intersects the photoresist layer and the conductive layer of FIG. 6B, in accordance with certain aspects of the present disclosure.

FIG. 6D illustrates a cross-sectional view of another dielectric material filled in the other cavity between segments of the conductive layer of FIG. 6C, in accordance with certain aspects of the present disclosure.

FIG. 7A illustrates a top view and a cross-sectional view of a photoresist layer with a cavity disposed above a dielectric layer, in accordance with certain aspects of the present disclosure.

FIG. 7B illustrates a top view and a cross-sectional view of a dielectric material filled in the cavity of the photoresist layer of FIG. 7A, in accordance with certain aspects of the present disclosure.

FIG. 7C illustrates a top view and a cross-sectional view of another cavity that intersects the photoresist layer and the dielectric layer of FIG. 7B, in accordance with certain aspects of the present disclosure.

FIG. 7D illustrates a top view and a cross-sectional view of another dielectric material filled in the other cavity of the dielectric layer of FIG. 7C, in accordance with certain aspects of the present disclosure.

FIG. 8A illustrates a top view and a cross-sectional view of a first dielectric layer with a cavity disposed above a second dielectric layer, in accordance with certain aspects of the present disclosure.

FIG. 8B illustrates a top view and a cross-sectional view of dielectric material filled in the cavity of the first dielectric layer of FIG. 8A, in accordance with certain aspects of the present disclosure.

FIG. 8C illustrates a top view and a cross-sectional view of a spacer formed from the dielectric material and embedded in the first dielectric layer of FIG. 8B, in accordance with certain aspects of the present disclosure.

FIG. 9A illustrates a cross-sectional view of a dielectric spacer embedded in a dielectric layer, in accordance with certain aspects of the present disclosure.

FIG. 9B illustrates a cross-sectional view of a photoresist layer with a cavity disposed above the dielectric layer of FIG. 9A, in accordance with certain aspects of the present disclosure.

FIG. 9C illustrates a cross-sectional view of additional cavities formed in the dielectric layer of FIG. 9B, in accordance with certain aspects of the present disclosure.

FIG. 9D illustrates a cross-sectional view of a trench formed in the photoresist layer of FIG. 9C, in accordance with certain aspects of the present disclosure.

FIG. 9E illustrates a cross-sectional view of additional trenches formed in the dielectric layer of FIG. 9D, in accordance with certain aspects of the present disclosure.

FIG. 10 is a flow diagram of example operations for fabricating an integrated circuit, in accordance with certain aspects of the present disclosure.

### DETAILED DESCRIPTION

Aspects of the present disclosure generally relate to methods of fabricating integrated circuits with an electrically insulating spacer between conductive layers. In the micro-electronic technology industry, there is a continuous demand and evolution of processes, technologies, and assembly methodologies to design and implement smaller, more efficient integrated circuits (ICs). To achieve the smaller IC size, the IC may be fabricated with fine architectural designs inside and outside a package substrate. For instance, fine architectural designs may include smaller interconnect feature sizes and design rules, such as a minimum metal trace width, a minimum metal trace spacing, a conductive via pad size, a via drill size, a reduced die bump pitch, or a reduced printed circuit board (PCB)-level interconnect pin pitch. In IC device design, the scaling of the IC may be limited by the metal enclosure (e.g., size and shape) of a conductive via (e.g., a through-silicon via) and the width of insulating spacers that electrically separate adjacent conductors of a conductive layer (e.g., conductors of metal layer two (M2)).

The spacing between conductors (e.g., conductive traces) of a conductive layer may limit the access (e.g., electrical routing) to terminals of various electrical devices, such as active electrical devices (e.g., transistors), capacitors, inductors, resistors, etc. For example, the width of an insulating spacer disposed between the conductors may span across multiple conductors of another conductive layer (e.g., metal layer one (M1) disposed below the conductors) limiting the location of vias that interconnect the conductors of different conductive layers (e.g., between M1 and M2). Due to certain fabrication processes, the closest that the conductive vias can be disposed adjacent to each other is with at least two conductors of the other conductive layer between the vias. This may leave some electrical devices (e.g., transistors) disconnected and/or waste space in the integrated circuit.

Aspects of the present disclosure provide a method of fabricating an insulating spacer that enables a reduced width between conductors of a conductive layer. The insulating spacer may be referred to as a spacer-based conductor cut, which provides electrical separation between conductors disposed on the same layer. In certain aspects, the spacer-based conductor cut may provide a mold between the conductors, where the mold may be filled in with a relatively low width insulating spacer. In other aspects, the spacer-based conductor cut may be formed before an additive process is used to deposit the conductors. The insulating spacers described herein may facilitate improved access to the terminals of various electrical devices or components, for example, through conductive vias that are spaced closer together. In certain aspects, the width of the insulating spacer may span across one conductor of a first conductive layer disposed below conductors of a second conductive layer. That is, the width of the insulating spacer may have an effective space for at most one conductor between the conductors of the second layer. In certain aspects, the width of the insulating spacer may span between two conductors of the first conductive layer. That is, the conductors of the second conductive layer may be laterally spaced from each other without an effective space for another conductor therebetween. Such a case may enable conductive vias to be electrically coupled to directly adjacent conductors of the first conductive layer, which may greatly improve the layout efficiency of the integrated circuit. The fabrication methods described herein may also provide high accuracy and improved control of forming the width of the insulating spacer between conductors of a conductive layer as further described herein.

FIG. 1 is a cross-sectional view of an example integrated circuit 100 that has an electrically insulating spacer disposed between conductors of a conductive layer, in accordance with certain aspects of the present disclosure. As shown, the integrated circuit 100 may include a substrate 102, a dielectric region 104, an active electrical device 106 (e.g., a transistor), dielectric layers 108, local conductive interconnects 110 (e.g., source-drain conductive contacts which are often abbreviated as CA), a first conductive layer 112 (e.g., metal layer one M1), conductive vias 114, a second conductive layer 116 (e.g., metal layer two M2), and an insulating spacer 118. In certain aspects, the integrated circuit 100 may include additional conductive vias 120, additional conductive layers 122 (e.g., metal layer three M3), under-bump conductive pads 124, and solder bumps 126.

The substrate 102 may be, for example, a semiconductor wafer including a silicon wafer. The dielectric region 104 may be disposed above the substrate 102. The dielectric region 104 may comprise an oxide, such as silicon dioxide. The dielectric region 104 may be a shallow trench isolation (STI) region configured to electrically isolate the active electrical device 106 from other electrical components, such as other electrical devices.

The active electrical device 106 may be disposed above the substrate 102. In this example, the active electrical device 106 may include one or more transistors. In certain aspects, the active electrical device 106 may be an inverter, amplifier, and/or other suitable electrical devices comprising transistors. The local conductive interconnects 110 may be electrically coupled to the active electrical device 106. For example, the source and/or drain of the active electrical device 106 may be electrically coupled to the local conductive interconnects 110, which are electrically coupled to the first conductive layer 112. In certain aspects, the active electrical device 106 may be formed during a front-end-of-line (FEOL) fabrication process.

In aspects, the first and second conductive layers 112, 116 may be disposed above electrical components (e.g., the active electrical device 106) formed during a BEOL fabrication process of the integrated circuit 100. The first conductive layer 112 may be the closest conductive layer disposed above the active electrical device 106, and the second conductive layer 116 may be the next closest conductive layer disposed above the active electrical device 106. In aspects, the second conductive layer may be disposed closer to the electrical components (e.g., the active electrical device 106) relative to other conductive layers (e.g., the additional conductive layers 122) formed during the back-end-of-line fabrication process The conductive vias 114 may be electrically coupled between the first conductive layer 112 and second conductive layer 116. In aspects, the conductive vias 114 may be through-silicon vias (TSVs).

The insulating spacer 118 may be a dielectric spacer including a dielectric material. The insulating spacer 118 may be effectively disposed in the second conductive layer 116, such that the insulating spacer 118 electrically separates conductors (116A, 116B) of the second conductive layer 116. For example, the insulating spacer may have a width of less than 5 nm (e.g., 3 nm, 2 nm, 1 nm, or less).

The conductive layers 112, 116, 122 provide electrical routing between the active electrical device 106 and other electrical components, including capacitors, inductors, resistors, an integrated passive device, a power management IC, a memory chip, etc. The first conductive layer 112, second conductive layer 116, conductive vias 114, and the insulating spacer 118 may be formed during a back-end-of-line fabrication process of the integrated circuit 100.

In this example, the integrated circuit 100 may be a flip-chip ball grid array (FC-BGA) integrated circuit having multiple solder bumps 126 electrically coupled to the under-bump conductive pads 124. In other cases, the integrated circuit 100 may have conductive pillars (e.g., copper (Cu) pillars) that electrically couple the integrated circuit 100 to other package substrates or a circuit board.

### Example Spacer-Based Conductor Cut

FIGS. 2A and 2B illustrate top views of various examples of an insulating spacer (e.g., the insulating spacer 118), in accordance with certain aspects of the present disclosure. The insulating spacer depicted in FIGS. 2A and 2B may be embedded in any suitable integrated circuit, such as the integrated circuit 100.

As shown in FIG. 2A, the insulating spacer 118 along with the conductors 116A, 116B of a second conductive layer (e.g., the second conductive layer 116) are disposed above the conductors 112A, 112B, 112C of a first conductive layer (e.g., the first conductive layer 112). The insulating spacer 118 may have a width that spans the width of the conductor 112B of the first conductive layer. As the insulating spacer 118 is disposed between the conductors 116A, 116B, the conductors 116A, 116B may be spaced from each other based on the width of the insulating spacer 118. Expressed another way, the conductors 116A, 116B of the second conductive layer may be laterally spaced from each other with at most an effective space for another conductor 112B disposed between the conductors 112A, 112C. With such a narrow width, each of the conductive vias 114 may be electrically coupled to the next adjacent conductor 112A, 112C of the first conductive layer and one of the conductors 116A, 116B of the second conductive layer. That is, the vias 114 may be spaced from each other with at most an effective space for the other conductor 112B disposed between the conductors 112A, 112C.

Referring to FIG. 2B, the insulating spacer 118 may have a width that spans the distance between adjacent conductors 112A, 112B of the first conductive layer (e.g., the first conductive layer 112). Expressed another way, the conductors 116A, 116B of the second conductive layer may be laterally spaced from each other without an effective space for another conductor disposed between the conductors 112A, 112B. With such a narrow width, each of the conductive vias 114 may be electrically coupled to adjacent conductors 112A, 112B of the first conductive layer and one of the conductors 116A, 116B of the second conductive layer. In this example, the insulating spacer 118 enables the closest possible spacing between vias 114 (e.g., without an effective space for another conductor disposed between the conductors 112A, 112B) and greatly improves the access to terminals of the various electrical devices disposed below the first conductive layer, such as the active electrical device 106. That is, the vias 114 may be spaced from each other without an effective space for another conductor disposed between the conductors 112A, 112B.

FIGS. 3A-3C illustrate example operations for fabricating a spacer, in accordance with certain aspects of the present disclosure. The operations may be performed by an integrated circuit processing facility, for example. Each of the FIGS. 3A-3C illustrates a top view of the fabrication process of the spacer, as well as a cross-sectional view taken across line A-A. In aspects, the spacer may be the insulating spacer 118 and/or a masking spacer that enables the formation of an insulating spacer as further described herein.

As shown in FIG. 3A, a photoresist layer 302 (e.g., a layer of a photoresist material) may be disposed above a dielectric layer 304. A first cavity 306 may be formed in the photoresist layer 302. In certain aspects, the first cavity 306 may be shaped as a mandrel or an open-ended box to provide a mold for the spacer. In certain cases, the first cavity 306 may be formed using a photolithography process to remove portions of the photoresist layer 302. In aspects, the dielectric layer 304 may include a dielectric material (e.g., silicon dioxide (SiO₂)), a hard mask material (e.g., titanium nitride (TiN)), and/or a low-κ dielectric material, which may include a material with a smaller dielectric constant (κ) than silicon dioxide.

Referring to FIG. 3B, the first cavity 306 may be filled with a dielectric material 308 (e.g., silicon nitride). A second cavity 310 may be formed in the dielectric material 308 such that the dielectric material 308 remaining in the first cavity is disposed on (e.g., conforms to) lateral surfaces 312 of the photoresist layer 302 in the first cavity 306. In other words, at this stage, there may be little to none of the dielectric material 308 remaining on a bottom surface of the second cavity 310. In certain cases, to form the second cavity 310, an etching process (e.g., a wet etching process) and/or drilling process (e.g., laser drilling) may be used to remove a portion of the dielectric material 308 in the first cavity 306.

As depicted in FIG. 3C, a spacer 314 (e.g., a dielectric spacer and/or insulating spacer) may be formed by removing multiple segments of the remaining dielectric material 308 in the first cavity 306 and/or portions of the photoresist layer 302. In certain aspects, the spacer 314 may include a segment 316 of the dielectric material and/or one or more segments 318A, 318B of the photoresist layer 302. For example, the segment 316 of the dielectric material may be a portion of the remaining dielectric material that engaged a single lateral surface of the first cavity. The width of the spacer 314 may be adjusted based on the size of the second cavity 310 and/or the presence or absence of the one or more segments 318A, 318B of the photoresist layer 302. In certain aspects, additional photoresist material may be added in the second cavity 310 to facilitate the fabrication of the segment 318A of the photoresist layer 302 and a wider spacer 314.

As shown in the top view of FIG. 3C, conductors 320 may be formed adjacent to the spacer 314 as further described herein, such that the conductors 320 are laterally spaced from each other based at least in part on a width 322 of the spacer 314. For example, each of the conductors 320 may engage different lateral surfaces of the spacer 314. In aspects, the conductors 320 may be conductors of a conductive layer (e.g., the second conductive layer 116) of an integrated circuit.

In certain aspects, multiple spacers may be formed from the segments of the remaining dielectric material in the first cavity. Referring to FIG. 3C across line B-B, two spacers 314A, 314B may be formed while removing segments of the remaining dielectric material. As shown, the spacers 314A, 314B may be laterally spaced from each other, for example, on opposite sides of the first cavity 306. In aspects, conductors 320A, 320B may be formed adjacent to the spacers 314A, 314B such that the conductors 320A, 320B are laterally spaced from each other based on the widths of the spacers 314A, 314B and a distance between the spacers 314A, 314B. In certain aspects, an additional conductor 320C may be formed between the spacers 314A, 314B. The additional conductor 320C may provide further electrical routing options of an integrated circuit between terminals of an electrical device. For example, the additional conductor 320C may provide a contact pad for a conductive via (e.g., the additional conductive via 120).

The conductors may be formed using various fabrication methods including various additive (e.g., damascene) processes (e.g., adding a conductor based on the width of the spacer) and/or etching processes (e.g., removing a portion of a conductor based on the width of the spacer). As an example of an additive process, FIGS. 4A-4C illustrate cross-sectional views of example operations for forming the conductors adjacent to the spacer 314, in accordance with certain aspects of the present disclosure. The operations may be performed by an integrated circuit processing facility, for example. As shown in FIG. 4A, after forming the spacer 314 above the dielectric layer 304, an additional photoresist layer 402 may be formed above the dielectric layer 304 and surrounding the spacer 314.

Referring to FIG. 4B, a first trench 404A and a second trench 404B may be formed in the dielectric layer 304, for example, using the photoresist layer 402 and the spacer 314 as patterning masks for the trenches 404A, 404B. The trenches 404A, 404B may be laterally spaced from each other based on the width of the spacer 314, which, in this example, serves as a mask to form the insulating spacer 318 between the trenches 404A, 404B. The insulating spacer 118 may be formed from a remaining segment of the dielectric layer 304 disposed between the trenches 404A, 404B.

As depicted in FIG. 4C, the conductors 320 may be formed by filling the trenches 404A, 404B with a conductive material, for example, including aluminum, copper, cobalt, gold, tungsten, titanium, etc. As an example, the conductive material may be deposited in the trenches 404A, 404B using a deposition process (e.g., an electroplating process, electroless deposition, or a chemical bath deposition), and any overfill of the conductive material may be removed using a planarization process such as a chemical-mechanical polishing (CMP) process.

In certain aspects, the spacer 314, which is formed using the operations described herein with respect to FIGS. 3A-3C, may be the insulating spacer (e.g., the insulating spacer 118) disposed between the conductors of a conductive layer (e.g., the second conductive layer 116). As another example of an additive process, FIGS. 5A-5D illustrate example operations for forming the conductors adjacent to the spacer 314, in accordance with certain aspects of the present disclosure. The operations may be performed by an integrated circuit processing facility, for example.

FIG. 5A illustrates a top view of the fabrication process of the conductors, as well as a cross-sectional view taken across line A-A. As shown, after forming the spacer 314 above the dielectric layer 304, an additional dielectric layer 502 may be formed above the dielectric layer 304 and surrounding the spacer 314. Referring to FIG. 5B, an additional photoresist layer 504 may be formed above the additional dielectric layer 502.

As depicted in FIG. 5C, a first trench 506A and a second trench 506B may be formed in the dielectric layer 502, for example, using the photoresist layer 505 and the spacer 314 as patterning masks for the trenches 506A, 506B. The trenches 506A, 506B may be laterally spaced from each other based on the width of the spacer 314, which, in this example, is disposed between the trenches 506A, 506B. In this example, the insulating spacer 118 may be formed from the spacer 314.

Referring to FIG. 5D, the conductors 320 may be formed by filling the trenches 506A, 506B with a conductive material, for example, including aluminum, copper, cobalt, gold, tungsten, titanium, etc. As an example, the conductive material may be deposited in the trenches 506A, 506B using a deposition process (e.g., an electroplating process, electroless deposition, or a chemical bath deposition), and any overfill of the conductive material may be removed using planarization process, such as a CMP process.

In certain aspects, the spacer may be used as a patterning mask for an etching process to remove a portion of a conductive material and form separate conductors. For example, FIGS. 6A-6D illustrate example operations for fabricating a spacer, in accordance with certain aspects of the present disclosure. The operations may be performed by an integrated circuit processing facility, for example. Each of the FIGS. 6A-6C illustrates a top view of the fabrication process of the spacer, as well as a cross-sectional view taken across line A-A.

As shown in FIG. 6A, a photoresist layer 602 (e.g., a layer of a photoresist material) may be disposed above a conductive layer 604. The first cavity 606 may be formed in the photoresist layer 602. In certain aspects, the first cavity 606 may be shaped as a mandrel or an open-ended box to provide a mold for the spacer. In certain cases, the first cavity 606 may be formed using a photolithography process to remove portions of the photoresist layer 602. In aspects, the conductive layer 604 may include a conductive material, such as aluminum, copper, cobalt, gold, tungsten, titanium, etc.

Referring to FIG. 6B, the first cavity 606 may be filled with a dielectric material 608 (e.g., silicon nitride). A second cavity 610 may be formed in the dielectric material 608 such that the dielectric material 608 remaining in the first cavity is disposed on (e.g., conforms to) lateral surfaces 612 of the photoresist layer 602 in the first cavity 606. In certain cases, to form the second cavity 610, an etching process (e.g., a wet etching process) and/or drilling process (e.g., laser drilling) may be used to remove a portion of the dielectric material 608 in the first cavity 606.

As depicted in FIG. 6C, the second cavity 610 may be filled with a photoresist material 614, which may serve as portion of a patterning mask to etch the conductive layer 604. A third cavity 616 may be formed through a portion of the remaining dielectric material 608 and a portion of the conductive layer 604. The portion of the remaining dielectric material 608, which serves as a patterning mask for the third cavity 616, may be considered the spacer, which controls the width of the insulating spacer 620 disposed between the conductors of a conductive layer as described below with respect to FIG. 6D. For instance, to form the third cavity 616, an etching process (e.g., a wet etching process) and/or drilling process (e.g., laser drilling) may be used to remove a portion of the dielectric material 608 and the conductive layer 604. The third cavity 616 may separate the conductive layer 604 into two separate conductors 618A, 618B (e.g., the conductors 116A, 116B). The third cavity 616 may have a width including at least the width of the remaining dielectric material 608 disposed adjacent to a lateral surface of the first cavity 606.

Referring to FIG. 6D showing a cross-sectional view of the conductors and insulating spacer, at least a portion of the third cavity 616 is filled with another dielectric material 620 (e.g., silicon nitride), such that the other dielectric material 620 is the insulating spacer disposed between the conductors 618A, 618B (e.g., the conductors 116A, 116B) of a conductive layer (e.g., the second conductive layer 116).

In certain aspects, the spacer may be used as a patterning mask to remove a portion of a dielectric material and then perform an additive process to fabricate the conductors, for example, as described herein with respect to FIGS. 5B-5D. For instance, suppose the same operations as described herein with respect to FIGS. 6A-6C are performed to cut a dielectric layer, for example, where the photoresist layer 602 is disposed above a dielectric layer 704 rather than the conductive layer 604 as illustrated in FIGS. 7A-7C. The operations may be performed by an integrated circuit processing facility, for example.

The operations associated with FIGS. 7A and 7B may be identical to the operations described herein with respect to FIGS. 6A and 6B, except that the photoresist layer 602 is disposed above the dielectric layer 704.

Referring to FIG. 7C, the second cavity 610 is filled with the photoresist material 614, which may serve as a portion of a patterning mask to etch the dielectric layer 704. The third cavity 616 is formed through a portion of the remaining dielectric material 608 and a portion of the dielectric layer 704. The portion of the remaining dielectric material 608, which serves as a patterning mask for the third cavity 616, may be considered the spacer, which controls the width of the insulating spacer 720 disposed between the conductors of a conductive layer as further described herein with respect to FIG. 7D. For instance, to form the third cavity 616, an etching process (e.g., a wet etching process) and/or drilling process (e.g., laser drilling) may be used to remove a portion of the dielectric material 608 and the dielectric layer 704.

As shown in FIG. 7D, at least a portion of the third cavity 616 is filled with another dielectric material 720 (e.g., silicon nitride), such that the other dielectric material 720 serves as the insulating spacer with respect to an additive process to fabricate the conductors, for example, as described herein with respect to FIGS. 5B-5D.

In certain aspects, the spacer may be the insulating spacer in an additive process to fabricate the conductors, for example, as described herein with respect to FIGS. 5B-5D. For example, FIGS. 8A-8C illustrate example operations for fabricating a spacer, in accordance with certain aspects of the present disclosure. The operations may be performed by an integrated circuit processing facility, for example. Each of the FIGS. 8A-8C illustrates a top view of the fabrication process of the spacer, as well as a cross-sectional view taken across line A-A.

As shown in FIG. 8A, a first dielectric layer 802 may be disposed above a second dielectric layer 804. A first cavity 806 may be formed in the first dielectric layer 802. In certain aspects, the first cavity 306 may be shaped as a mandrel or an open-ended box to provide a mold for the spacer. In certain cases, the first cavity 306 may be formed using an etching process (e.g., wet etching) and/or a drilling process (e.g., laser drilling) to remove portions of the first dielectric layer 802. In aspects, the dielectric layers 804, 802 may include a dielectric material (e.g., silicon dioxide), a hard mask material (e.g., titanium nitride (TiN)), and/or a low-κ dielectric material, which may include a material with a smaller dielectric constant than silicon dioxide. While the examples provided herein are described with respect to there being separate first and second dielectric layers (802, 804), in certain aspects, the first and second dielectric layers (802, 804) may be considered different portions (e.g., sub-layers) of the same dielectric layer.

Referring to FIG. 8B, the first cavity 806 may be filled with a dielectric material 808 (e.g., silicon nitride). A second cavity 810 may be formed in the dielectric material 808 such that the dielectric material 808 remaining in the first cavity is disposed adjacent (e.g., conforms to) lateral surfaces 812 of the first dielectric layer 802 in the first cavity 306. In certain cases, to form the second cavity 810, an etching process (e.g., a wet etching process) and/or drilling process (e.g., laser drilling) may be used to remove a portion of the dielectric material 808 in the first cavity 806.

As depicted in FIG. 8C, a spacer 814 (e.g., a dielectric spacer and/or insulating spacer) may be formed by removing multiple segments of the remaining dielectric material 808 in the first cavity 806. In certain aspects, the spacer 814 may include a segment 816 of the dielectric material 808. For example, the segment 816 of the dielectric material may be a portion of the remaining dielectric material that engaged a single lateral surface of the first cavity. The width of the spacer 814 may be adjusted based on the size of the second cavity 310. After forming the spacer 814, the first cavity 806 may be filled with an additional dielectric material 822. With the spacer embedded in the first dielectric layer 802, conductors of a conductive layer (e.g., the second conductive layer 116) may be formed within the first dielectric layer 802 using an additive process, for example, as described herein with respect to FIGS. 5B-5D.

FIGS. 9A-9E illustrate cross-sectional views of example operations for fabricating an insulating spacer having a width that spans the distance between adjacent conductors of a conductive layer (e.g., the first conductive layer 112), for example, as described herein with respect to FIG. 2B, in accordance with certain aspects of the present disclosure. As shown in FIG. 9A, an insulating spacer 118 may be formed in a dielectric layer 902, for example, using any of the various operations described herein for forming the insulating spacer in a dielectric layer (e.g., as described herein with respect to FIGS. 5A, 7D, or 8C).

Referring to FIG. 9B, a photoresist layer 904 may be formed above the dielectric layer 902. A first cavity 906 may be formed in the photoresist layer 302. In certain aspects, the first cavity 906 may be shaped as a mandrel or an open-ended box to provide the patterning for through-hole-vias. The first cavity 906 may span across the width of the insulating spacer 118 and extend past the insulating spacer 118. In other words, the first cavity 906 may overlap the insulating spacer 118 and have greater width than the insulating spacer 118. In certain cases, the first cavity 906 may be formed using a photolithography process to remove portions of the photoresist layer 904.

As depicted in FIG. 9C, a second cavity 910 and third cavity 912 may be formed in the dielectric layer 902, where the second and third cavities 910, 912 are formed on opposite sides of and adjacent to the insulating spacer 118. In certain aspects, an etching process (e.g., wet etching process) and/or drilling process (e.g., laser drilling) may be used to form the third and second cavities 910, 912 through the dielectric layer 902. The second and third cavities 910, 912 provide molds for conductive vias (e.g., the conductive vias 114) that electrically couple the two conductive layers. For instance, the second cavity 910 may intersect the dielectric layer 902 until a surface of the conductor 112A of a conductive layer disposed below the insulating spacer 118 is exposed. The second and third cavities 910, 912 are contiguous with the first cavity 906. In other words, the first cavity 906 may include the second and third cavities 910, 912, such that the second and third cavities 910, 912 expand the first cavity 906 into the dielectric layer 902.

As shown in FIG. 9D, the first cavity 906 may be expanded into a first trench 914 removing a portion of the photoresist layer 904. The first trench 914 may provide a patterning mask for the conductors disposed adjacent to the insulating spacer 118. In certain cases, the first trench 914 may be formed using a photolithography process to remove portions of the photoresist layer 904.

Referring to FIG. 9E, the first trench 914 may be expanded to include a second trench 916 and a third trench 918 by removing portions of the dielectric layer 902 on opposite lateral surfaces of the insulating spacer 118. The second trench 916 is contiguous with the second cavity 910, and the third trench 918 is contiguous with the third cavity 912. The second and third trenches 916, 918 provide molds for adjacent conductors (e.g., the conductors 116A, 116B of FIG. 2B) that are electrically separated by the insulating spacer 118. As such, the second and third trenches 916, 918 as well as the second and third cavities 910, 912 may be filled with a conductive material to form the conductive vias and conductors described herein with respect to FIG. 2B. In aspects, filling the second and third trenches 916, 918 as well as the second and third cavities 910, 912 with a conductive material may include a deposition process (e.g., an electroplating process, electroless deposition, or chemical bath deposition). Any overfill of the conductive material may be removed using a planarization process, for example, a CMP process. In aspects, the insulating spacer 118 enables the closest possible spacing between vias and the conductors of a conductive layer (e.g., the second conductor layer 116). In certain aspects, the insulating spacer 118 greatly improves the access to terminals of various electrical devices disposed below the conductors 112A, 112B, such as the active electrical device 106 depicted in FIG. 1.

FIG. 10 is a flow diagram of example operations 1000 for fabricating an integrated circuit (e.g., the integrated circuit 100 of FIG. 1), in accordance with certain aspects of the present disclosure. The operations 1000 may be performed by an integrated circuit fabrication facility, for example.

The operations 1000 begin, at block 1002, by forming a first cavity (e.g., the first cavity 306, the first cavity 606, or the first cavity 806) in a first layer (e.g., the photoresist layer 302, the photoresist layer 602, or the first dielectric layer 802) disposed above a second layer (e.g., the dielectric layer 304, the conductive layer 604, the dielectric layer 704, or the second dielectric layer 804). At block 1004, at least a portion of the first cavity may be filled with a dielectric material (e.g., the dielectric material 308, the dielectric material 608, or the dielectric material 808) disposed above the second layer. At block 1006, a second cavity (e.g., the second cavity 310, the second cavity 610, the second cavity 810) may be formed in the dielectric material such that the dielectric material remaining in the first cavity is disposed on (e.g., conforms to) lateral surfaces (e.g., the lateral surface 312, the lateral surface 612, the lateral surface 812) of the first layer in the first cavity. At block 1008, a dielectric spacer (e.g., the spacer 314, the dielectric material 620, the dielectric material 720, the segment 816 of the dielectric material 808) may be formed comprising a segment of the remaining dielectric material in the first cavity. At block 1010, a first conductor (e.g., one of the conductors 320, the first conductor 618A, one of the conductors 820) may be formed in the first layer or the second layer, where the first conductor is laterally spaced from a second conductor (e.g., e.g., one of the conductors 320, the second conductor 618B, one of the conductors 820) based at least in part on a width of the dielectric spacer.

In certain aspects, the first layer and the second layer are formed during a back-end-of-line process and above semiconductor layers of an active device.

In certain aspects, forming the dielectric spacer at block 1008 may include the operations described herein with respect to FIGS. 3A-3C. With respect to operations 1000, for example, forming the dielectric spacer at block 1008 may include removing a plurality of segments of the remaining dielectric material and removing portions of the first layer adjacent to the plurality of segments of the remaining dielectric material, for example, as depicted in FIG. 3C. In aspects, the first layer is a photoresist layer, and the second layer is a dielectric layer. In certain aspects, the dielectric spacer may include at least one segment of the first layer (e.g., a portion of the photoresist layer) adjacent to the segment of the remaining dielectric material. In certain cases, an additional segment of photoresist material may be formed adjacent to the dielectric spacer. For instance, the operations 1000 may further include forming a segment of a photoresist material (e.g., the segment 318A) adjacent to the segment of the remaining dielectric material. In certain aspects, at block 1010, the first conductor and second conductor of operations 1000 may be formed in accordance with an additive process, for example, the process described herein with respect to FIGS. 4A-4C.

In certain aspects, the operations 1000 may also include forming an additional spacer, for example, in accordance with the operations described herein with respect to FIG. 3C. For example, the operations 1000 may further comprise forming another dielectric spacer comprising another segment of the remaining dielectric material. With respect to operations 1000, forming the first conductor at block 1010 may comprise forming the first conductor (e.g., the first conductor 320A) laterally spaced from the second conductor (e.g., the second conductor 320B) based on the width of the dielectric spacer (e.g., the spacer 314A), a width of the other dielectric spacer (e.g., the spacer 314B), and a distance between the dielectric spacer and the other dielectric spacer. In aspects, the dielectric spacer and the other dielectric spacer are disposed on opposite sides of the first cavity. In certain aspects, a third conductor (e.g., the conductor 320C) may be formed between the dielectric spacer and the other dielectric spacer.

In certain aspects, the dielectric spacer, which is formed using the operations described herein with respect to FIGS. 3A-3C, may be the insulating spacer (e.g., the insulating spacer 118) disposed between the conductors of a conductive layer (e.g., the second conductive layer 116). For instance, the operations 1000 may further comprise forming another dielectric material (e.g., the dielectric layer 502) around the dielectric spacer, for example, as described herein with respect to FIG. 5A. In certain aspects, at block 1010, the first conductor and second conductor of operations 1000 may be formed in accordance with an additive process, for example, the additive process described herein with respect to FIGS. 5A-5D.

In certain aspects, forming the dielectric spacer at block 1008 may include performing the operations described herein with respect to FIGS. 6A-6D or 7A-7D. With respect to operations 1000, for example, forming the dielectric spacer at block 1008 may include filling in the second cavity with a photoresist material (e.g., the photoresist material 614). The operations 1000 may also include forming a third cavity (e.g., the third cavity 616), having at least the width of the dielectric spacer, through the segment of the remaining dielectric material and through a portion of the second layer, and filling at least a portion of the third cavity with another dielectric material (e.g., the other dielectric material 620). In certain cases, the first layer may be a photoresist layer (e.g., the photoresist layer 602), and the second layer may be an electrically conductive layer (e.g., the conductive layer 604), and forming the first and second conductors of operations 1000 may include separating the second layer into two segments. For example, the first conductor may include a first segment of the second layer, the second conductor may include a second segment of the second layer, and the other dielectric material disposed in the third cavity is between the first conductor and the second conductor. In other cases, the first layer may be a photoresist layer (e.g., the photoresist layer 602), and the second layer may be a dielectric layer (e.g., the dielectric layer 704), where the dielectric spacer forms the insulating spacer 118 during an additive process to fabricate the conductors, for example, as described herein with respect to FIGS. 5B-5D and 7A-7D.

In certain aspects, forming the dielectric spacer at block 1008 may include performing the operations described herein with respect to FIGS. 8A-8C. With respect to operations 1000, for example, forming the dielectric spacer at block 1008 may include removing a plurality of segments of the remaining dielectric material in the first cavity, and filling at least a portion of the first cavity with another dielectric material. In aspects, the first layer may be a first dielectric layer (e.g., the first dielectric layer 802), and the second layer may be a second dielectric layer (e.g., the second dielectric layer 804).

According to certain aspects, the first and second conductors may be formed (including at block 1010) using various additive processes. For example, the first and second conductors may be formed using an additive process as described herein with respect to FIG. 4A-4C. With respect to operations 1000, forming the first conductor at block 1010 may include forming a first trench (e.g., the first trench 404A) and a second trench (e.g., the second trench 404B) in the second layer, and forming the first conductor (e.g., one of the conductors 320) in the first trench and the second conductor (e.g., one of the conductors 320) in the second trench. Forming the first and second conductors may include depositing a conductive material in the trenches. In aspects, the second trench is laterally spaced from the first trench based at least in part on the width of the dielectric spacer, and a segment of the second layer is disposed between the first and second trenches.

In other cases, the first and second conductors may be formed using an additive process as described herein with respect to FIGS. 5B-5D. With respect to operations 1000, forming the first conductor at block 1010 may include forming another dielectric material (e.g., the dielectric layer 502) around the dielectric spacer, forming a photoresist layer (e.g., the photoresist layer 504) above the dielectric spacer, forming a first trench (e.g., the first trench 506A) and a second trench (e.g., the second trench 506B) on opposite sides of the dielectric spacer through the second layer, and forming the first conductor in the first trench and the second conductor in the second trench.

In aspects, the operations 1000 facilitate forming the dielectric spacer with the closest possible spacing between through-hole vias and the conductors of a conductive layer (e.g., the second conductor layer 116). For example, the first conductor may be laterally spaced from the second conductor without an effective space for another conductor disposed between the first conductor and the second conductor as described herein with respect to FIG. 2B. In other aspects, the first conductor may be laterally spaced from the second conductor with at most an effective space for another conductor disposed between the first conductor and the second conductor as described herein with respect to FIG. 2A.

In certain aspects, the first conductor and the second conductor are formed during a back-end-of-line fabrication process of the integrated circuit. The first conductor and the second conductor may be included in a conductive layer disposed above electrical components (e.g., the active electrical device 106) formed during a front-end-of-line fabrication process of the integrated circuit. In aspects, the conductive layer is disposed closest to the electrical components relative to other conductive layers (e.g., the additional conductive layers 122) formed during the back-end-of-line fabrication process.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

The following description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. A method of fabricating an integrated circuit, comprising:
forming a first cavity in a first layer disposed above a second layer;
filling at least a portion of the first cavity with a dielectric material disposed above the second layer;
forming a second cavity in the dielectric material such that the dielectric material remaining in the first cavity is disposed on lateral surfaces of the first layer in the first cavity;
forming a dielectric spacer comprising a segment of the remaining dielectric material in the first cavity; and
forming a first conductor, in the first layer or the second layer, that is laterally spaced from a second conductor based at least in part on a width of the dielectric spacer.

2. The method of claim 1, wherein forming the dielectric spacer comprises:
removing a plurality of segments of the remaining dielectric material; and
removing portions of the first layer adjacent to the plurality of segments of the remaining dielectric material, wherein the first layer is a photoresist layer and wherein the second layer is a dielectric layer.

3. The method of claim 2, wherein the dielectric spacer comprises at least one segment of the first layer adjacent to the segment of the remaining dielectric material.

4. The method of claim 2, further comprising forming a segment of a photoresist material adjacent to the segment of the remaining dielectric material.

5. The method of claim 2, further comprising forming another dielectric material around the dielectric spacer.

6. The method of claim 2, further comprising forming another dielectric spacer comprising another segment of the remaining dielectric material, wherein forming the first conductor comprises forming the first conductor laterally spaced from the second conductor based on the width of the dielectric spacer, a width of the other dielectric spacer, and a distance between the dielectric spacer and the other dielectric spacer.

7. The method of claim 6, further comprising:
forming a third conductor disposed between the dielectric spacer and the other dielectric spacer.

8. The method of claim 6, wherein the dielectric spacer and the other dielectric spacer are disposed on opposite sides of the first cavity.

9. The method of claim 1, wherein forming the dielectric spacer comprises filling in the second cavity with a photoresist material, wherein the first layer is a photoresist layer, and wherein the second layer is a conductive layer.

10. The method of claim 9, wherein forming the first conductor comprises:
forming a third cavity, having at least the width of the dielectric spacer, through the segment of the remaining dielectric material and through a portion of the second layer; and
filling at least a portion of the third cavity with another dielectric material, wherein the first conductor comprises a first segment of the second layer, wherein the second conductor comprises a second segment of the second layer, and wherein the other dielectric material disposed in the third cavity is between the first conductor and the second conductor.

11. The method of claim 1, wherein forming the dielectric spacer comprises:
removing a plurality of segments of the remaining dielectric material in the first cavity; and
filling at least a portion of the first cavity with another dielectric material, wherein the first layer is a first dielectric layer and wherein the second layer is a second dielectric layer.

12. The method of claim 1, wherein forming the first conductor comprises:
forming a first trench and a second trench in the second layer, wherein the second trench is laterally spaced from the first trench based at least in part on the width of the dielectric spacer, and wherein a segment of the second layer is disposed between the first and second trenches; and
forming the first conductor in the first trench and the second conductor in the second trench.

13. The method of claim 1, wherein forming the first conductor comprises:
forming another dielectric material around the dielectric spacer;
forming a photoresist layer above the dielectric spacer;
forming a first trench and a second trench on opposite sides of the dielectric spacer through the second layer; and
forming the first conductor in the first trench and the second conductor in the second trench.

14. The method of claim 1, wherein the first conductor is laterally spaced from the second conductor without an effective space for another conductor disposed between the first conductor and the second conductor.

15. The method of claim 1, wherein the first conductor and the second conductor are formed during a back-end-of-line fabrication process of the integrated circuit.

16. The method of claim 15, wherein the first conductor and the second conductor are included in a conductive layer disposed above electrical components formed during a front-end-of-line fabrication process of the integrated circuit.

17. The method of claim 16, wherein the conductive layer is disposed closest to the electrical components relative to other conductive layers formed during the back-end-of-line fabrication process.

18. An integrated circuit, comprising:
a first conductive layer comprising a first conductor and a second conductor laterally spaced from the first conductor;
a second conductive layer disposed above the first conductive layer, wherein the second conductive layer comprises a third conductor and a fourth conductor laterally spaced from the third conductor;
a first via disposed between the first conductive layer and the second conductive layer and electrically coupled to the first conductor and the third conductor;
a second via disposed between the first conductive layer and the second conductive layer and electrically coupled to the second conductor and the fourth conductor; and
an insulating spacer disposed between the third conductor and the fourth conductor, wherein the third conductor is laterally spaced from the fourth conductor by a distance between the first conductor and the second conductor with or without an effective space for a single conductor disposed between the first conductor and the second conductor.

19. The integrated circuit of claim 18, wherein the insulating spacer is further disposed between the first conductor and the second conductor.

20. The integrated circuit of claim 18, wherein the insulating spacer includes a dielectric material and electrically separates the third conductor from the fourth conductor.
